(19) United States
(12) Patent Application Publication
(10) Pub. No.: US 2021/0336067 A1
(43) Pub. Date: Oct. 28, 2021

(54) SEMICONDUCTOR COMPONENT AND METHOD OF FABRICATING THEREOF

(71) Applicant: WUHAN CHINA STAR OPTOELECTRONICS TECHNOLOGY CO., LTD., Wuhan (CN)

(72) Inventor: Donghui Xiao, Wuhan (CN)

(73) Assignee: WUHAN CHINA STAR OPTOELECTRONICS TECHNOLOGY CO., LTD., Wuhan (CN)

(21) Appl. No.: 16/467,697

(22) PCT Filed: Jan. 11, 2019
(86) PCT No.: PCT/CN2019/071289

§ 371 Date: Jun. 7, 2019

(30) Foreign Application Priority Data
Nov. 30, 2018 (CN) 201811452431.6

(51) Int. Cl. H01L 29/786; H01L 29/66; H01L 21/265

(52) U.S. Cl. CPC H01L 29/78672; H01L 21/265; H01L 29/6675; H01L 29/78633

(57) ABSTRACT

A semiconductor component includes a substrate; a polysilicon layer formed on the substrate, and the polysilicon layer includes a source, a channel, and a drain, and the source and the drain are formed at two sides of the polysilicon layer, and the channel is formed between the source and the drain; a gate insulating layer formed on the polysilicon layer; a gate formed on the gate insulating layer and formed directly above the channel; an interlayer dielectric layer formed above the gate and covering the gate and implanted with hydrogen atoms by ion implantation and rapidly annealed at high temperature to form a hydrogenated interlayer dielectric layer; a metal conducting wire passing through an upper surface of the hydrogenated interlayer dielectric layer and contacting with the source or the drain; and a passivation layer covering the hydrogenated interlayer dielectric layer. A method of fabricating the semiconductor component is also provided.

### BACKGROUND OF INVENTION

### Field of Invention

The present invention relates to a semiconductor component and method of fabricating thereof, and more particularly, to a semiconductor component formed in a low temperature polysilicon process.

### Description of Prior Art

During a low temperature polysilicon process for fabricating semiconductor components of thin film transistors, high temperature treatment must be performed to remove hydrogen atoms after forming an amorphous silicon layer, so that many defects in subsequent processes resulted from hydrogen bond cleavage can be avoided. The defects are mostly caused by bond cleavage of silicon, so that hydrogen is used to repair the bond cleavage of silicon, which is called hydrogenation. However, in prior art, hydrogen content in an interlayer dielectric layer is not uniform, and temperature uniformity of rapid thermal annealing is poor. Furthermore, hydrogenation temperature of the interlayer dielectric layer is different from temperature of rapid thermal annealing of the interlayer dielectric layer, so that ions are activated at different temperatures. Therefore, insufficient hydrogenation or excessive hydrogenation is occurred, and it is necessary to provide an method for improvement to solve the problems existing in the prior art.

### SUMMARY OF INVENTION

A main object of the present invention is to provide a semiconductor component which can improve a defect such as insufficient hydrogenation or hydrogenation unevenness of a transistor in a low temperature polysilicon process.

According to one embodiment of the present invention, a semiconductor component of a thin film of transistor formed in a low temperature polysilicon process is provided. The semiconductor component includes a substrate; a polysilicon layer formed on the substrate, and the polysilicon layer includes a source, a channel, and a drain, and the source and the drain are formed at two sides of the polysilicon layer, and the channel is formed between the source and the drain; a gate insulating layer formed on the polysilicon layer; a gate formed on the gate insulating layer, and the gate is formed directly above the channel; an interlayer dielectric layer, and the interlayer dielectric layer is formed above the gate and covers the gate, and the interlayer dielectric layer is implanted with hydrogen atoms by ion implantation and rapidly annealed at high temperature to form a hydrogenated interlayer dielectric layer; a metal conducting wire passing through an upper surface of the hydrogenated interlayer dielectric layer and contacting with the source or the drain; and a passivation layer covering the hydrogenated interlayer dielectric layer.

In one embodiment of the present invention, the semiconductor component further includes a pixel electrode.

In one embodiment of the present invention, a light shielding layer formed between the substrate and the polysilicon layer.

In one embodiment of the present invention, the polysilicon layer includes silicon oxide and silicon nitride.

In one embodiment of the present invention, the ion implantation further implants hydrogen atoms into the channel.

According to another embodiment of the present invention, a method of fabricating a semiconductor component includes providing a substrate; forming a polysilicon layer on the substrate, and the polysilicon layer includes a source, a channel, and a drain, and the source and the drain are formed at two sides of the polysilicon layer, and the channel is formed between the source and the drain; forming a gate insulating layer formed on the polysilicon layer; forming a gate on the gate insulating layer, and the gate is formed directly above the channel; forming an interlayer dielectric layer above the gate, and the interlayer dielectric layer covers the gate, and the interlayer dielectric layer is implanted with hydrogen atoms by ion implantation and rapidly annealed at high temperature to form a hydrogenated interlayer dielectric layer; forming a metal conducting wire, and the metal conducting wire extends through an upper surface of the hydrogenated interlayer dielectric layer and contacts with the source or the drain; forming a passivation layer, and the passivation layer covers the hydrogenated interlayer dielectric layer.

In one embodiment of the present invention, the method further includes forming a pixel electrode.

In one embodiment of the present invention, the method further includes forming a light shielding layer between the substrate and the polysilicon layer.

In one embodiment of the present invention, the polysilicon layer comprises silicon oxide and silicon nitride.

In one embodiment of the present invention, the ion implantation further implants hydrogen atoms into the channel.

Embodiments of the present invention provide a semiconductor component which is directly implanted with hydrogen atoms, and the hydrogen atoms are implanted into a channel to achieve a hydrogenation effect, and the uniformity of ion implantation is good, so that the uniformity of hydrogenation is excellent.

### BRIEF DESCRIPTION OF DRAWINGS

FIG. 1 is a flow chart showing the fabrication of a semiconductor component according to one embodiment of the present invention.

FIG. 2 is a schematic view of a semiconductor component having a low temperature polysilicon thin film transistor according to one embodiment of the present invention.

### DETAILED DESCRIPTION OF PREFERRED EMBODIMENTS

In order to make the present invention more comprehensible, the preferred embodiments are described below in detail with reference to the accompanying drawings.

In one embodiment of the present invention, a semiconductor component of thin film transistor is provided. The semiconductor component comprises a substrate, a polysilicon layer formed on the substrate, a source and a drain formed at two sides of the polysilicon layer, a channel formed between the source and the drain, a gate insulating layer formed on the polysilicon layer, a gate formed on the gate insulating layer, an interlayer dielectric layer formed above the gate and covering the gate, a metal conducting wire passing through an upper surface of a hydrogenated interlayer dielectric layer, and a passivation layer covering the hydrogenated interlayer dielectric layer. Specifically, the gate is formed directly above the channel, and the interlayer dielectric layer is implanted with hydrogen atoms by ion implantation and rapidly annealed at high temperature to form a hydrogenated interlayer dielectric layer. The metal conducting wire extends through an upper surface of the hydrogenated interlayer dielectric layer and contacts with the source or the drain. In another embodiment of the present invention, the semiconductor component further comprises a pixel electrode.

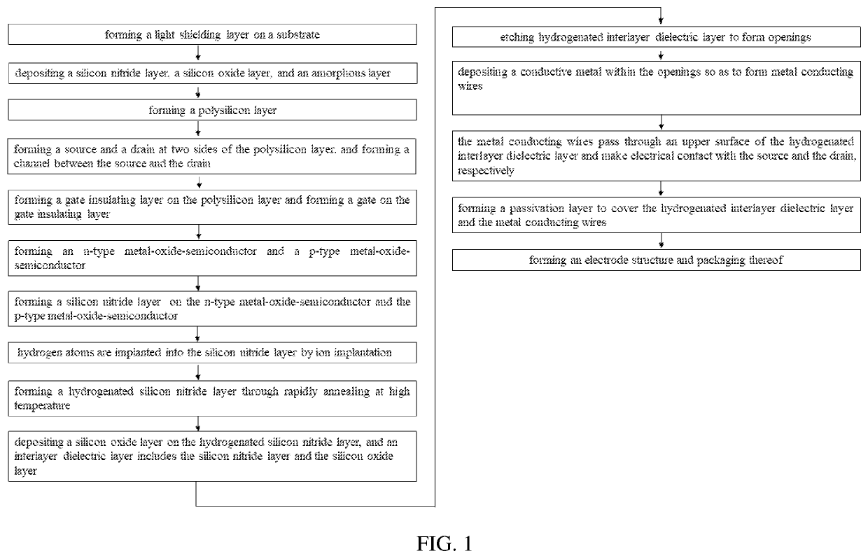

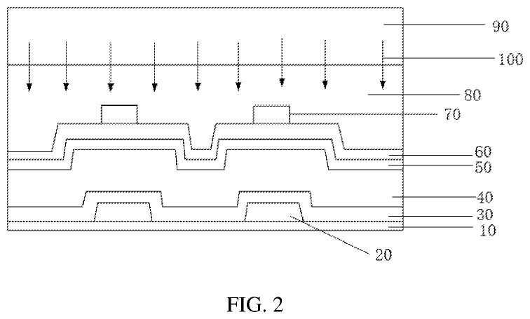

Please referring to FIG. 1 and FIG. 2, in a low temperature polysilicon process for fabricating a semiconductor component of a thin film transistor, a light shielding layer 20 is firstly formed on a substrate 10, and the light shielding layer 20 can prevent an occurrence of light leakage, and then a silicon nitride layer 30, a silicon oxide layer 40, and an amorphous polysilicon layer are deposited. The amorphous polysilicon layer is formed to be a polysilicon layer 50 by excimer-laser annealing (ELA). The light shielding layer 20 is disposed between the substrate 10 and the polysilicon layer 50. After forming the polysilicon layer 50, a source and a drain are formed at two sides of the polysilicon layer 50 by ion implantation, and a channel is formed between the source and the drain. Then, a gate insulating layer 60 is formed on the polysilicon layer 50 and a gate 70 is formed on the gate insulating layer 60, and the gate is disposed directly above the channel. Next, an n-type metal-oxide-semiconductor (n-MOS) and a p-type metal-oxide-semiconductor (p-MOS) are formed, and an interlayer dielectric layer is formed on the n-type metal-oxide-semiconductor and the p-type metal-oxide-semiconductor, and the interlayer dielectric layer covers the gate 70. The interlayer dielectric layer comprises a silicon nitride layer 80 and a silicon oxide layer 90. It should be noted that unsaturated bonds are formed during a crystallization process for forming the polysilicon layer 50. The unsaturated bonds cause charge carrier traps which affect the movement of electric charge in the channel, so that threshold voltage of a low temperature polysilicon thin film transistor for polarizing is affected. Accordingly, in the embodiment of the present invention, in order to improve current-voltage characteristics of the low temperature polysilicon thin film transistor and decrease the threshold voltage value of the thin film transistor, the interlayer dielectric layer is implanted with hydrogen atoms by ion implantation and then rapidly annealed at high temperature to form a hydrogenated interlayer dielectric layer. In detail, the interlayer dielectric layer is formed by two steps. Firstly, the silicon nitride layer 80 is formed, and the silicon nitride layer 80 is implanted with hydrogen atoms by the ion implantation 100 and then rapidly annealed at high temperature to form a hydrogenated silicon nitride layer 80. Specifically, a rapidly annealing step is performed at 450° C., and the silicon oxide layer 90 is deposited on the hydrogenated silicon nitride layer 80. The ion implantation has a property of high evenness and can further implant hydrogen atoms into the channel to achieve a hydrogenation effect, and therefore the hydrogenation has good evenness. Then, the hydrogenated interlayer dielectric layer 100 is etched to form openings, and a conductive metal is deposited within the openings so as to form metal conducting wires (not shown). The metal conducting wires pass through an upper surface of the hydrogenated interlayer dielectric layer and make electrical contact with the source or the drain (not shown). A passivation layer⋅(not shown) is subsequently formed to cover the hydrogenated interlayer dielectric layer and the metal conducting wires. Then, common electrodes and pixel electrodes connected to the metal conducting wires are formed according to the actual situation in the art, and finally the semiconductor component of the thin film transistor is packaged, and therefore it will not be described again.

In the above, the present application has been described in the above preferred embodiments, but the preferred embodiments are not intended to limit the scope of the invention, and a person skilled in the art may make various modifications without departing from the spirit and scope of the application. The scope of the present application is determined by claims.

What is claimed is:

1. A semiconductor component, comprising:
a substrate;
a polysilicon layer, wherein the polysilicon layer is formed on the substrate, the polysilicon layer comprises a source, a channel, and a drain, and the source and the drain are formed at two sides of the polysilicon layer, and the channel is formed between the source and the drain;
a gate insulating layer, wherein the gate insulating layer is formed on the polysilicon layer;
a gate, wherein the gate is formed on the gate insulating layer, and the gate is formed directly above the channel;
an interlayer dielectric layer, wherein the interlayer dielectric layer is formed above the gate and covers the gate, and the interlayer dielectric layer is implanted with hydrogen atoms by ion implantation and rapidly annealed at high temperature to form a hydrogenated interlayer dielectric layer;
a metal conducting wire, wherein the metal conducting wire extends through an upper surface of the hydrogenated interlayer dielectric layer and contacts with the source or the drain;
a passivation layer, wherein the passivation layer covers the hydrogenated interlayer dielectric layer;
a pixel electrode, wherein the pixel electrode is connected to the metal conducting wire; and
a light shielding layer, wherein the light shielding layer is formed between the substrate and the polysilicon layer.

2. The semiconductor component according to claim 1, wherein the polysilicon layer comprises silicon oxide and silicon nitride.

3. The semiconductor component according to claim 1, wherein, the ion implantation further implants hydrogen atoms into the channel.

4. A semiconductor component, comprising:
a substrate;
a polysilicon layer, wherein the polysilicon layer is formed on the substrate, the polysilicon layer comprises a source, a channel, and a drain, the source and the drain are formed at two sides of the polysilicon layer, and the channel is formed between the source and the drain;
a gate insulating layer, wherein the gate insulating layer is formed on the polysilicon layer;
a gate, wherein the gate is formed on the gate insulating layer, and the gate is formed directly above the channel;
an interlayer dielectric layer, wherein the interlayer dielectric layer is formed above the gate and covers the gate, and the interlayer dielectric layer is implanted with hydrogen atoms by ion implantation and rapidly annealed at high temperature to form a hydrogenated interlayer dielectric layer;
a metal conducting wire, wherein the metal conducting wire extends through an upper surface of the hydrogenated interlayer dielectric layer and contacts with the source or the drain; and
a passivation layer, wherein the passivation layer covers the hydrogenated interlayer dielectric layer.

5. The semiconductor component according to claim 4, wherein the semiconductor component further comprises a pixel electrode connected to the metal conducting wire.

6. The semiconductor component according to claim 4, wherein a light shielding layer formed between the substrate and the polysilicon layer.

7. The semiconductor component according to claim 4, wherein the polysilicon layer comprises silicon oxide and silicon nitride.

8. The semiconductor component according to claim 4, wherein the ion implantation further implants hydrogen atoms into the channel.

9. A method of fabricating a semiconductor component, comprising:
providing a substrate;
forming a polysilicon layer on the substrate, wherein the polysilicon layer comprises a source, a channel, and a drain, and the source and the drain are formed at two sides of the polysilicon layer, and the channel is formed between the source and the drain;
forming a gate insulating layer formed on the polysilicon layer;
forming a gate on the gate insulating layer, and the gate is formed directly above the channel;
forming an interlayer dielectric layer above the gate, wherein the interlayer dielectric layer covers the gate, and the interlayer dielectric layer is implanted with hydrogen atoms by ion implantation and rapidly annealed at high temperature to form a hydrogenated interlayer dielectric layer;
forming a metal conducting wire, wherein the metal conducting wire extends through an upper surface of the hydrogenated interlayer dielectric layer and contacts with the source or the drain;
forming a passivation layer, wherein the passivation layer covers the hydrogenated interlayer dielectric layer.

10. The method of fabricating the semiconductor component according to claim 9, wherein the method further comprises forming a pixel electrode.

11. The method of fabricating the semiconductor component according to claim 9, wherein the method further comprises forming a light shielding layer between the substrate and the polysilicon layer.

12. The method of fabricating the semiconductor component according to claim 9, wherein the polysilicon layer comprises silicon oxide and silicon nitride.

13. The method of fabricating the semiconductor component according to claim 9, wherein the ion implantation further implants hydrogen atoms into the channel.
